(19) United States
(12) Patent Application Publication
(10) Pub. No.: US 2025/0215559 A1
(43) Pub. Date: Jul. 3, 2025

(54) INDIUM COMPOUND, INDIUM-CONTAINING THIN FILM DEPOSITION COMPOSITION COMPRISING SAME, AND INDIUM-CONTAINING THIN FILM MANUFACTURING METHOD

(71) Applicant: DNF CO., LTD., Daejeon (KR)

(72) Inventors: Yonghee KWONE, Daejeon (KR); Taeseok BYUN, Daejeon (KR); Sangyong JEON, Daejeon (KR); Sangchan LEE, Daejeon (KR); Youngjae IM, Daejeon (KR); Sangick LEE, Daejeon (KR)

(21) Appl. No.: 18/852,970

(22) PCT Filed: Mar. 27, 2023
(86) PCT No.: PCT/KR2023/004034

§ 371 Date: Sep. 30, 2024

(30) Foreign Application Priority Data
Apr. 14, 2022 (KR) 10-2022-0046350

(51) Int. Cl. C23C 16/40

(52) U.S. Cl. CPC C23C 16/407

(57) ABSTRACT

The present invention provides a novel indium compound, a preparation method therefor, an indium-containing thin film deposition composition comprising same, and an indium-containing thin film manufacturing method employing same. A high quality indium-containing thin film, which contains uniform components, can be manufactured to have a stable deposition rate.

### TECHNICAL FIELD

The present invention relates to a novel indium compound, a method for preparing the same, a composition for thin film deposition containing indium comprising the same, and a method for manufacturing an indium-containing thin film using the same.

### BACKGROUND ART

Next-generation displays have been developed with the goal of low power consumption, high resolution, and high reliability. To achieve this goal, thin film transistor (TFT) materials with high charge mobility are required.

Thin films are used in a variety of important applications such as semiconductor device fabrication and nanotechnology. These applications include, for example, a conductive film, a high-refractive index optical coating, an anti-corrosion coating, a photocatalytic self-cleaning glass coating, a biocompatible coating, a gate dielectric insulating film in a field effect transistor (FET), dielectric capacitor layers, a capacitor electrode, a gate electrode, an adhesive diffusion barrier, an integrated circuit, etc. Thin films are also used in microelectronic applications such as high-k dielectric oxides for dynamic random access memory (DRAM) applications, and ferroelectric perovskites used in infrared detectors and non-volatile ferroelectric random access memories (NV-FeFAMs). The continued miniaturization of microelectronic components has increased the need for the use of such dielectric thin films.

Previously, amorphous silicon was used for thin film transistors, but recently, metal oxides that have higher charge mobility than silicon and are easier to a process at a lower temperature than polycrystalline silicon have been used. As these metal oxides, materials to which various types of metal atoms such as indium and zinc are added are used, and a metal oxide thin film is manufactured by processes such as sputtering, atomic layer deposition (ALD), pulsed laser deposition (PLD), and chemical vapor deposition (CVD).

Indium is widely used for transparent electrodes due to its excellent transparency and electrical conductivity. When an indium (In)-containing metal thin film is formed by sputtering using a sputter target, there is a limit to uniformly adjusting a composition of the thin film because a composition of a deposited thin film is determined by a sputter target. In addition, it is difficult to maintain a uniform composition and thickness of the thin film during large-area deposition, making it difficult to obtain uniform film properties. In addition, when the film is manufactured by chemical vapor deposition (CVD) instead of sputtering, an indium precursor such as trimethylindium (CAS NO. 3385-78-2), which has been used previously, is mostly solid, so there is a problem in terms of vapor pressure control and reproducibility of a uniform film. In particular, most indium (In) precursors are thermally decomposed at high temperatures of 250° C. or more, making it difficult to obtain high-quality thin films, and there are also limitations in obtaining thin films having a uniform thickness and a constant multi-component composition during large-area deposition.

Therefore, there is a need to develop a high-quality indium precursor that has excellent thermal stability at high temperatures and is uniformly deposited.

### DISCLOSURE

### Technical Problem

An object of the present invention is to provide a novel indium compound having improved physical and chemical properties and a method for preparing the same.

Another object of the present invention is to provide a composition for thin film deposition containing indium having high volatility comprising the novel indium compound.

Another object of the present invention is to provide a method for manufacturing a uniform indium-containing thin film exhibiting an improved deposition rate using the composition for thin film deposition containing indium.

### Technical Solution

In one general aspect, there is provided an indium compound represented by the following Formula 1:

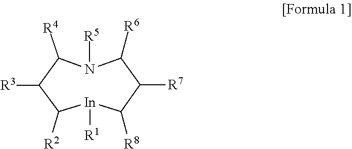

wherein
R¹ to R⁸ are each independently hydrogen, C₁-C₇alkyl, C₂-C₇alkenyl, C₂-C₇alkynyl, C₆-C₁₂aryl, C₆-C₁₂arylC₁-C₇alkyl, C₃-C₁₀cycloalkyl, or C₁-C₇alkoxy.

The indium compound may have a thermal decomposition temperature of 250 to 500° C., and R¹ to R⁸ in Formula 1 may be each independently hydrogen, C₁-C₅alkyl, C₂-C₅alkenyl, C₂-C₅alkynyl, or C₁-C₅alkoxy, and more specifically, R¹ to R⁸ in Formula 1 may be each independently hydrogen or C₁-C₄alkyl.

An indium compound according to an embodiment of the present invention may be selected from the following compounds:

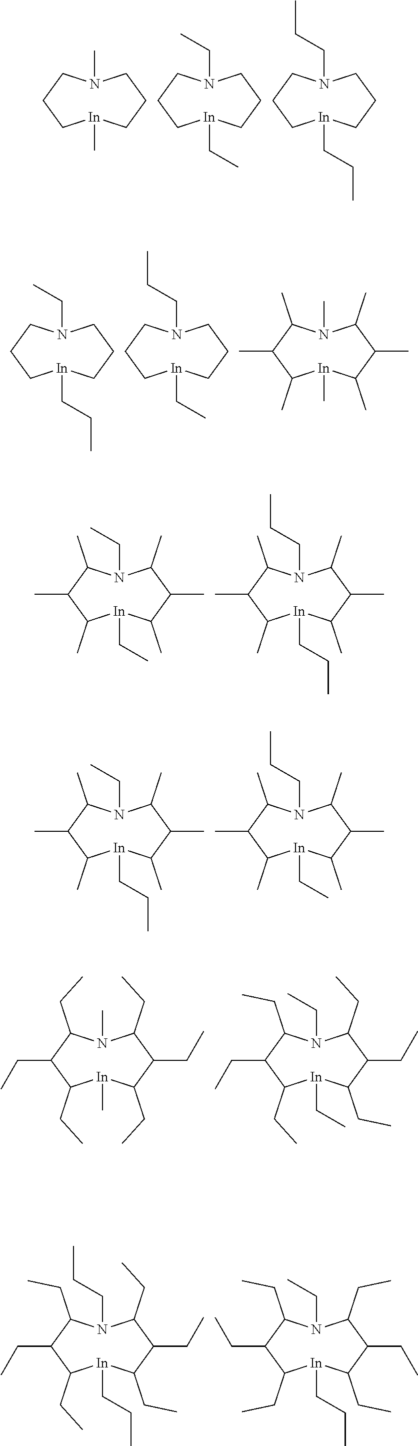

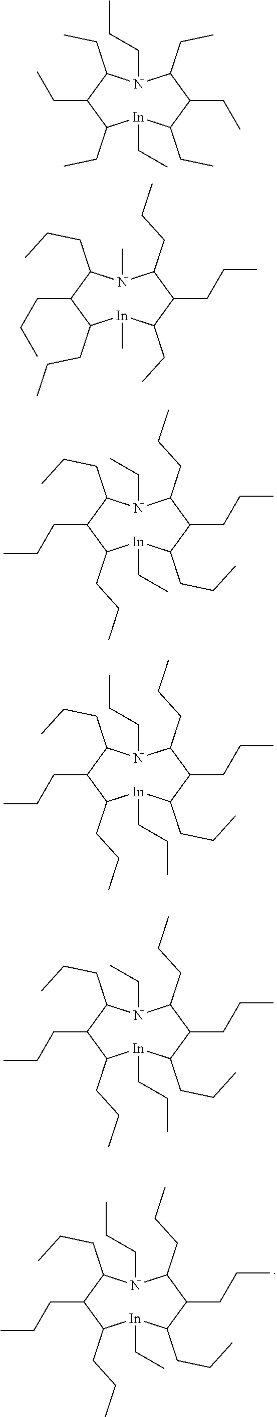

In another general aspect, there is provided a composition for thin film deposition containing indium, comprising an indium compound as described above. The composition for thin film deposition containing indium may further comprise a gallium precursor and a zinc precursor.

In another general aspect, there is provided a method for manufacturing an indium-containing thin film, the method including: a) raising a temperature of a substrate mounted in a chamber; b) injecting and adsorbing a composition for thin film deposition containing indium according to an embodiment of the present invention to the substrate of which the temperature is raised; and c) manufacturing an indium-containing thin film by injecting a reaction gas into the substrate to which the composition for thin film deposition containing indium is adsorbed.

The reaction gas may be any one or two or more selected from the group consisting of oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), amine, diamine, carbon monoxide (CO), carbon dioxide (CO₂), a saturated or unsaturated C₁ to C₁₂ hydrocarbon, hydrogen (H₂), argon (Ar), and helium (He).

In addition, a temperature of the substrate in step a) may be 200 to 600° C.

### Advantageous Effects

Since a novel indium compound according to the present invention exhibits improved physical and chemical properties, a composition for thin film deposition containing indium comprising the indium compound has high volatility and excellent thermal stability and storage stability.

In addition, the method for preparing the indium compound according to the present invention may produce an indium compound with a high yield through a mild and simple process, thereby facilitating industrial use.

Further, the method for manufacturing an indium-containing thin film according to the present invention may exhibit an improved and stable deposition rate by employing the composition for thin film deposition containing indium according to the present invention, may provide uniform step coverage for a three-dimensional device, and may provide a high-quality indium-containing thin film having uniform components and excellent electrical quality.

### DESCRIPTION OF DRAWINGS

FIG. 1 is a diagram illustrating a result of TGA analysis of an indium compound prepared in Example 1.

FIG. 2 is a diagram illustrating a result of DSC analysis of an indium compound prepared in Example 1.

### BEST MODE

Hereinafter, an indium compound according to the present invention, a composition for thin film deposition containing indium comprising the same, and a method for manufacturing an indium-containing thin film using the same will be described in detail.

Singular forms used herein are intended to include the plural forms as well unless otherwise indicated in context.

In addition, numerical ranges used herein include a lower limit, an upper limit, and all values within that range, increments that are logically derived from the type and width of the defined range, all double-defined values, and all possible combinations of upper and lower limits of numerical ranges defined in different forms. Unless otherwise specifically defined herein, values outside the numerical range that may arise due to experimental errors or rounded values are also included in the defined numerical range.

As used herein, the term “comprise” is an “open” description having the meaning equivalent to expressions such as “include,” “contain,” “have,” or “feature”, and does not exclude elements, materials, or process that are not further listed.

As used herein, “alkyl” refers to a straight-chain or branched non-cyclic hydrocarbon having 1 to 7 carbon atoms, and preferably 1 to 5 carbon atoms. In addition, in another aspect, alkyl may have 1 to 3 carbon atoms.

As used herein, “alkenyl” refers to a saturated straight-chain or branched acyclic hydrocarbon having at least one carbon-carbon double bond, and examples thereof include, but are not limited to, -vinyl, -allyl, -1-butenyl, -2-butenyl, -isobutenyl, -1-pentenyl, -2-pentenyl, -3-methyl-1-butenyl, -2-methyl-2-butenyl, -2,3-dimethyl-2-butenyl, -1-hexenyl, -2-hexenyl, -3-hexenyl, -1-heptenyl, -2-heptenyl, and -3-heptenyl. These alkenyl groups may be optionally substituted. Alkenyl includes radicals with cis and trans orientations, or alternatively, E and Z orientations.

As used herein, “alkynyl” refers to a saturated straight-chain or branched acyclic hydrocarbon having at least one carbon-carbon triple bond, and examples thereof include, but are not limited to, an ethynyl group, a propynyl group, a butynyl group, a butadiinyl group, a pentynyl group, a pentadiinyl group, a hexynyl group, a hexadinyl group, and isomers thereof.

As used herein, “cycloalkyl” refers to a monocyclic or polycyclic saturated ring containing carbon and hydrogen atoms and having no carbon-carbon multiple bonds. Examples of cycloalkyl include, but are not limited to, cyclopropyl, cyclobutyl, cyclopentyl, cyclohexyl, and cycloheptyl. The cycloalkyl group may be optionally substituted.

As used herein, “halogen” refers to fluorine, chlorine, bromine, or iodine.

As used herein, “aryl” refers to a carbocyclic aromatic group containing 5 to 12 ring atoms. Representative examples include, but are not limited to, phenyl, tolyl, xylyl, naphthyl, tetrahydronaphthyl, indenyl, azulenyl, etc. Furthermore, aryl includes a carbocyclic aromatic group and groups linked by alkylene or alkenylene, or also by one or more heteroatoms selected from B, O, N, C(═O), P, P(═O), S, S(═O)₂ and Si atoms.

As used herein, “alkoxy” refers to —O-(alkyl), including —OCH₃, —OCH₂CH₃, —O(CH₂)₂CH₃, —O(CH₂)₃CH₃, —O(CH₂)₄CH₃, —O(CH₂)₅CH₃, and the like, wherein the alkyl is as defined above.

The number of carbon atoms described in the present invention does not include the number of carbon atoms of the substituent. For example, C₁-C₇alkyl refers to an alkyl having 1 to 7 carbon atoms, which does not include the number of carbon atoms of the substituent of the alkyl.

Hereinafter, the present invention will be described in detail. Technical terms and scientific terms used herein have the general meaning understood by those skilled in the art to which the present invention pertains, unless otherwise defined, and a description for the known function and configuration unnecessarily obscuring the gist of the present invention will be omitted in the following description.

The present invention provides an indium compound represented by the following Formula 1:

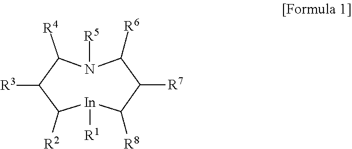

wherein
R¹ to R⁸ are each independently hydrogen, C₁-C₇alkyl, C₂-C₇alkenyl, C₂-C₇alkynyl, C₆-C₁₂aryl, C₆-C₁₂arylC₁-C₇alkyl, C₃-C₁₀cycloalkyl, or C₁-C₇alkoxy.

The indium compound may have a thermal decomposition temperature of 250 to 500° C., preferably 300 to 450° C., and more preferably 300 to 400° C.

In addition, the indium compound may exhibit a high deposition rate due to its higher volatility and improved vapor pressure, and is a compound having improved thermal stability, has excellent storage stability, and may be easier to handle.

In the indium compound according to an embodiment of the present invention, R¹ to R⁸ in Formula 1 may be each independently hydrogen, C₁-C₅alkyl, C₂-C₅alkenyl, C₂-C₅alkynyl, or C₁-C₅alkoxy. Specifically, R¹ to R⁸ in Formula 1 may be each independently hydrogen or C₁-C₄alkyl, and more specifically, R¹ to R⁸ in Formula 1 may be each independently hydrogen or C₁-C₃alkyl.

An indium compound according to an embodiment of the present invention may be represented by the following Formula 11:

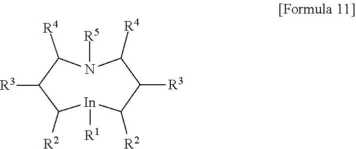

wherein

R¹ to R⁵ are each independently hydrogen, C₁-C₇alkyl, C₂-C₇alkenyl, C₂-C₇alkynyl, C₆-C₁₂aryl, C₆-C₁₂arylC₁-C₇alkyl, C₃-C₁₀cycloalkyl, or C₁-C₇alkoxy.

R¹ to R⁵ in Formula 11 may be each independently hydrogen, C₁-C₅alkyl, C₂-C₅alkenyl, C₂-C₅alkynyl, or C₁-C₅alkoxy. Specifically, R¹ to R⁵ in Formula 11 may be each independently hydrogen or C₁-C₄alkyl, and more specifically, R¹ to R⁵ in Formula 11 may be each independently hydrogen or C₁-C₃alkyl.

An indium compound according to an embodiment of the present invention may be selected from the following compounds:

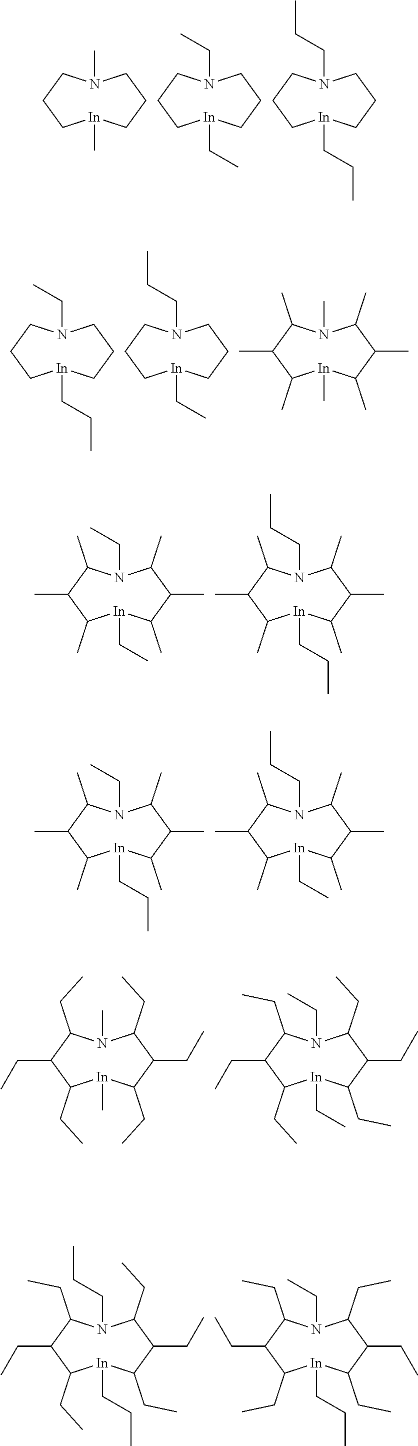

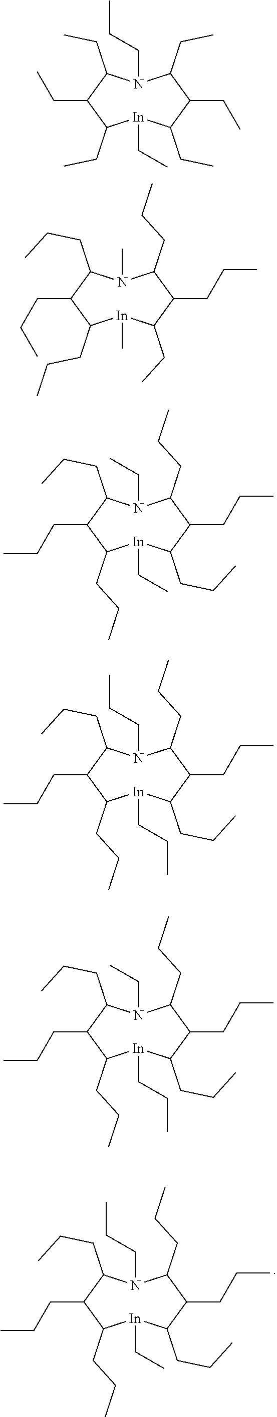

Specifically, the indium compound according to an embodiment may be selected from the following compounds:

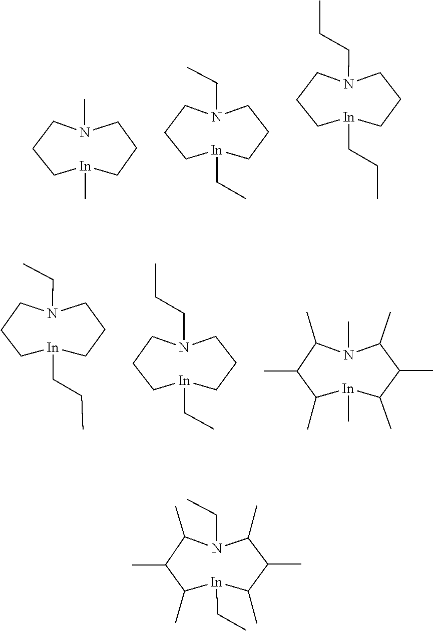

A method for preparing an indium compound represented by the following Formula 1 according to an embodiment of the present invention may include reacting a compound represented by the following Formula 2 with a compound represented by the following Formula 3:

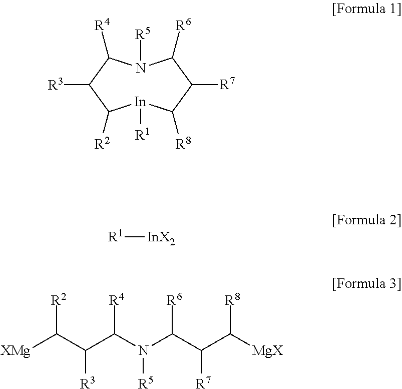

wherein
R¹ to R⁸ are each independently hydrogen, C₁-C₁₀alkyl, C₃-C₁₀alkenyl, C₃-C₁₀alkynyl, C₆-C₂₀aryl, C₆-C₂₀arylC₁-C₁₀alkyl, C₃-C₂₀cycloalkyl, or C₁-C₁₀alkoxy; and
X is a halogen.

In addition, the compound represented by Formula 2 may be prepared by reacting a compound represented by the following Formula 4 with a compound represented by the following Formula 5:

InX₃ [Formula 4]

R¹—MgX [Formula 5]
wherein
R¹ is each independently hydrogen, C₁-C₁₀alkyl, C₃-C₁₀alkenyl, C₃-C₁₀alkynyl, C₆-C₂₀aryl, C₆-C₂₀arylC₁-C₁₀alkyl, C₃-C₂₀cycloalkyl, or C₁-C₁₀alkoxy; and
X is a halogen.

The method for preparing an indium compound represented by Formula 1 may be carried out at a temperature used in conventional organic synthesis, but may vary depending on the amount of reactants and starting materials, and preferably −20 to 80° C., −10 to 60° C., and 0 to 40° C.

In addition, the solvent used in the preparation method may be any common organic solvent, but may be, but is not limited to, one or two or more selected from the group consisting of hexane, pentane, dichloromethane (DCM), dichloroethane (DCE), benzene, toluene, acetonitrile (MeCN), nitromethane, tetrahydrofuran (THF), N,N-dimethylformamide (DMF), and N,N-dimethylacetamide (DMA).

In the preparation method, each reaction may be terminated after confirming that a starting material is completely consumed through NMR, and after completion of the reaction, a process of separating and purifying the compound may be further performed through conventional methods such as extraction, distillation of the solvent under reduced pressure, and column chromatography.

The method for producing an indium compound may produce a high-purity indium compound in high yield and may be a mild and simple process, so that industrial use may be facilitated.

In addition, the present invention provides a composition for thin film deposition containing indium comprising an indium compound according to an embodiment.

The composition for thin film deposition containing indium may be used for a semiconductor thin film, and an IGZO thin film for displays. Also, as the composition for thin film deposition containing indium, the indium compound according to an embodiment may be used alone, and a mixture of the indium compound and one or two selected from gallium precursors and zinc precursors may be used.

Specifically, the gallium precursor may be trimethylgallium (TMG), and the zinc precursor may be diethylzinc (DEZ), but the present invention is not limited thereto.

The method for preparing an indium-containing thin film according to an embodiment of the present invention may be manufactured in a thin film having a multi-layer structure including dissimilar metals, wherein the thin film may have a stacked structure by sequentially depositing the composition for thin film deposition containing indium and a precursor of another metal, or may be deposited by mixing the composition for thin film deposition containing indium with a precursor of another metal.

In more detail, the thin film having a multi-layer structure may be IGZO (indium/gallium/zinc/oxide), and an atomic ratio of indium:gallium:zinc may be 1:0.1 to 5:0.1 to 10, preferably 1:0.1 to 3:0.3 to 5, and more preferably 1:1:1.

The composition for thin film deposition containing indium may have a constant vapor pressure during a deposition process, so that the composition of the thin film is kept constant, thereby producing a uniform thin film having constant components. Also, the composition for thin film deposition containing indium may exhibit excellent step coverage at the same time as having a uniform film thickness, thereby manufacturing a thin film showing significantly improved performance even in a three-dimensional device.

In particular, unlike other types of metals, indium-gallium-zinc oxide (IGZO) semiconductors are very valuable as active matrix materials for pixel-density and low-power screens due to their high mobility, excellent uniformity, and very low leakage current characteristics.

In addition, the present invention provides a method for manufacturing an indium-containing thin film, and the method of manufacturing an indium-containing thin film according to an embodiment may include: a) raising a temperature of a substrate mounted in a chamber; b) injecting and adsorbing a composition for thin film deposition containing indium according to an embodiment of the present invention to the substrate of which the temperature is raised; and c) manufacturing an indium-containing thin film by injecting a reaction gas into the substrate to which the composition for thin film deposition containing indium is adsorbed.

Specifically, the temperature of the substrate in step a) may be maintained at 200 to 600° C., specifically at 250 to 600° C., and more specifically at 300 to 500° C. It is possible to deposit a composition for thin film deposition containing indium even at a high temperature such as the above temperature without thermal decomposition of an indium compound, thereby improving stability of the deposition process and increasing productivity.

In addition, the indium-containing thin film, manufactured using the method for manufacturing an indium-containing thin film, may be manufactured by reducing the content of impurities such as carbon to manufacture a high-quality indium-containing thin film.

Substrates used in the method for manufacturing an indium-containing thin film according to an embodiment may include, but are not limited to, one or two or more substrates selected from the group consisting of glass, silicon, metal, polyester (PE), polyethyleneterephthalate (PET), polyethylenenaphthalate (PEN), polycarbonate (PC), polyetherimide (PEI), polyethersulfone (PES), polyetheretherketone (PEEK), and polyimide (PI).

In step b) of the method for manufacturing the indium-containing thin film, the composition for thin film deposition containing indium may be used by adding it in a stainless steel bubbler vessel and the temperature may be maintained at 70 to 130° C., specifically 80 to 120° C., and more specifically 90 to 110° C.

In addition, in step b), deposition conditions may be adjusted according to the structure or thermal characteristics of the desired thin film, and examples of the deposition conditions according to an embodiment include input flow rates of the indium compound, a reaction gas and a transfer gas, pressure, and RF power.

As a non-limiting example of such deposition conditions, the input flow rate of the indium compound may be adjusted in a range of 1 to 1,000 sccm in a bubbler type, the input flow rate of the transfer gas may be adjusted in a range of 1 to 5,000 sccm, the input flow rate of the reaction gas may be adjusted in a range of 10 to 5,000 sccm, and the pressure may be adjusted in a range of 0.1 to 10 torr, but the present invention is not limited thereto.

The injection time when the composition for thin film deposition containing indium is injected in step b) of the manufacturing method may be 1 to 30 seconds, preferably 1 to 20 seconds, and more preferably 2 to 10 seconds, and within this range, uniformity of a thickness of the thin film is improved, so that a uniform thin film may be manufactured even on a substrate having a complex shape.

The reaction gas in step c) of the manufacturing method may be, but is not limited to, any one or two or more selected from the group consisting of oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), amine, diamine, carbon monoxide (CO), carbon dioxide (CO₂), a saturated or unsaturated C₁-C₁₂ hydrocarbon, hydrogen (H₂), argon (Ar), and helium (He), specifically, any one or two or more selected from the group consisting of oxygen (O₂), ozone (O₃), distilled water (H₂O), and hydrogen peroxide (H₂O₂), and more specifically, oxygen (O₂) or ozone (O₃).

In an embodiment, the transfer gas in the manufacturing method may be an inert gas, and may be any one or two or more selected from the group consisting of argon (Ar), helium (He), and nitrogen (N₂), and specifically, nitrogen (N₂), but the present invention is not limited thereto.

A method for manufacturing an indium-containing thin film according to an embodiment may be performed at a temperature of 200 to 600° C., specifically at a temperature of 250 to 600° C., and more specifically at a temperature of 300 to 500° C.

The method for manufacturing an indium-containing thin film according to an embodiment may be carried out by repeating the cycle by taking steps b) and c) as one cycle, and the cycle may be carried out until a thin film having a desired thickness is formed, specifically, 100 to 5000 cycles, and more specifically, 500 to 2000 cycles, but the present invention is not limited thereto.

The method for manufacturing an indium-containing thin film according to an embodiment may further include performing a purge with a transfer gas, in order to remove unadsorbed composition after step b) and to remove reaction by-products and residual reaction gas after step c).

In addition, the method of manufacturing an indium-containing thin film according to an embodiment of the present invention may be performed by atomic layer deposition (ALD), chemical vapor deposition (CVD), metal organic chemical vapor deposition (MOCVD), low pressure vapor deposition (LPCVD), plasma enhanced vapor deposition (PECVD), or plasma enhanced atomic layer deposition (PEALD), and preferably atomic layer deposition (ALD), chemical vapor deposition (CVD), or metal organic chemical vapor deposition (MOCVD).

A thin film manufactured by the method for manufacturing an indium-containing thin film according to an embodiment of the present invention is uniform and exhibits an improved deposition rate, and thus may be a high-quality indium-containing thin film having uniform compositions and excellent electrical quality.

Hereinafter, an indium compound according to the present invention, a composition for thin film deposition containing indium comprising the same, and a method for manufacturing an indium-containing thin film using the same will be described in detail through specific examples.

However, the following Examples are only a reference for describing the present invention in detail, and the present invention is not limited thereto and may be implemented in various forms. In addition, the terms used in the description of the present invention are only for effectively describing specific embodiments, and are not intended to limit the present invention.

Further, unless otherwise noted, all examples were carried out using techniques for handling air-sensitive materials commonly known in the art, such as “Schlenk techniques” under an inert atmosphere, such as purified nitrogen (N₂) or argon (Ar).

### [Example 1] Synthesis of MeIn(Pr)₂NMe

To a flask equipped with a magnetic stirrer and a condenser, 8.5 g (0.35 mol) of Mg and 0.45 g (0.003 mol) of I₂ were added, followed by vacuum drying. 250 mL of THF was added thereto, and 1.52 g (0.014 mol) of bromoethane and 34.13 g (0.185 mol) of MeN(PrCl)₂ were added while maintaining the temperature at 60° C. After stirring at 60° C. for 8 hours, the reaction was terminated to synthesize MeN(PrMgCl)₂.

To a flask equipped with a magnetic stirrer and a condenser, 38.7 g (0.14 mol) of InCl₃ was added, and 200 mL of n-Hexane was added, followed by stirring while maintaining 10° C. To the flask, 58.3 mL of MeMgCl (3.0 M solution in THF) was slowly added and stirred at room temperature for 2 hours to synthesize MeInCl₂. To the flask, MeN(PrMgCl)₂ was slowly added while maintaining 10° C., stirred at room temperature for 8 hours, and the formation of a light gray precipitate was confirmed. After filtering the synthesized mixture, the solvent and volatile by-products were removed under reduced pressure, and the mixture was distilled under reduced pressure (61° C., 0.5 torr) to obtain 27 g of MeIn(Pr)₂NMe in a colorless liquid state (yield: 63%).

¹H NMR (400 MHZ, C6D6) δ 2.0 (m, 4H), 1.8 (s, 3H), 1.7 (m, 4H), 0.6 (m, 4H), −0.1 (s, 3H)

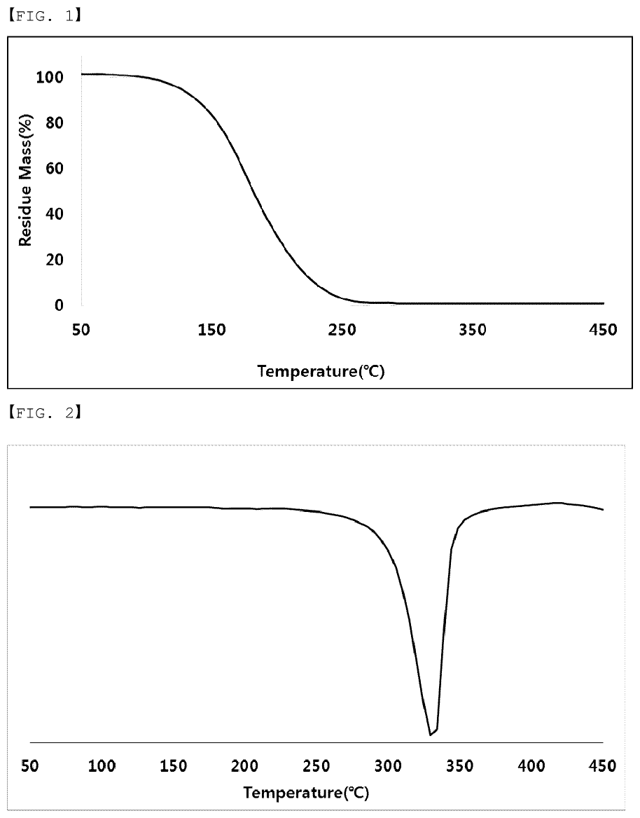

FIG. 1 illustrates a result of TGA analysis of MeIn(Pr)₂NMe prepared in Example 1, from which it can be seen that the indium compound of Example 1 has a single evaporation step at about 120° C., and that a residue mass at 500° C. is 0.8%, indicating rapid vaporization characteristics and vaporization of 99% or more without thermal decomposition. From these results, it can be seen that the indium compound of Example 1 has excellent thermal stability.

In addition, FIG. 2 illustrates a result of DSC analysis, wherein an endothermic peak was confirmed at about 340° C. Thus, it can be seen that the indium compound according to the present invention does not thermally decompose even at a high temperature of 250° C. or more, and thus has significantly improved thermal stability.

### [Example 2] Manufacture of Indium-Containing Thin Film

An indium-containing thin film was manufactured by atomic layer deposition (ALD) using the indium compound according to Example 1 and ozone (03) as a reaction gas.

A silicon substrate was mounted inside a deposition chamber, and the temperature of the substrate was maintained at 350° C. The MeIn(Pr)₂NMe prepared in Example 1 was charged into a stainless steel bubbler vessel and a temperature was maintained at 60° C.

The charged compound was injected into a deposition chamber for 3 seconds using nitrogen gas (100 sccm) as a transport gas. Purging was performed by injecting nitrogen gas (500 sccm) for 5 seconds to remove unadsorbed compounds remaining in the deposition chamber.

Ozone (500 sccm) was injected as a reaction gas for 5 seconds to deposit an indium-containing oxide thin film. Thereafter, purging was performed by injecting nitrogen gas (500 sccm) for 5 seconds to remove residual reaction gas and reaction by-products.

The indium-containing oxide thin film was manufactured by performing 1000 cycles with the above-described processes as one cycle. As a result of XPS analysis of the indium-containing oxide thin film, it was confirmed that the indium content and oxygen content were measured to be 38.4% and 58.3%, respectively, and a substantially high-purity indium oxide film was formed.

Accordingly, the indium compound according to an embodiment of the present invention is a compound in a liquid state and has improved thermal stability, high volatility, and improved vapor pressure. Thus, when a thin film is manufactured using the indium compound, it is possible to form a thin film with high reliability by exhibiting a uniform and stable deposition rate, to provide a uniform film thickness for a three-dimensional device, and to manufacture a thin film showing an excellent composition ratio of indium and oxygen.

Hereinabove, although the present invention has been described by specific matters, the limited embodiments, and Comparative Examples, they have been provided only for assisting in a more general understanding of the present invention. Therefore, the present invention is not limited to the exemplary embodiments. Various modifications and changes may be made by those skilled in the art to which the present invention pertains from this description.

Therefore, the spirit of the present invention should not be limited to the above-mentioned embodiments, but the claims and all of the modifications equal or equivalent to the claims are intended to fall within the scope and spirit of the present invention.

1. An indium compound represented by the following Formula 1: 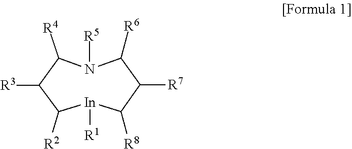
wherein R¹ to R⁸ are each independently hydrogen, C₁-C₇alkyl, C₂-C₇alkenyl, C₂-C₇alkynyl, C₆-C₁₂aryl, C₆-C₁₂arylC₁-C₇alkyl, C₃-C₁₀cycloalkyl, or C₁-C₇alkoxy.

2. The indium compound of claim 1, wherein the indium compound has a thermal decomposition temperature of 250 to 500° C.

3. The indium compound of claim 1, wherein R¹ to R⁸ in Formula 1 are each independently hydrogen, C₁-C₅alkyl, C₂-C₅alkenyl, C₂-C₅alkynyl, or C₁-C₅alkoxy.

4. The indium compound of claim 1, wherein R¹ to R⁸ in Formula 1 are each independently hydrogen or C₁-C₄alkyl.

5. The indium compound of claim 1, wherein the indium compound is selected from the following compounds:

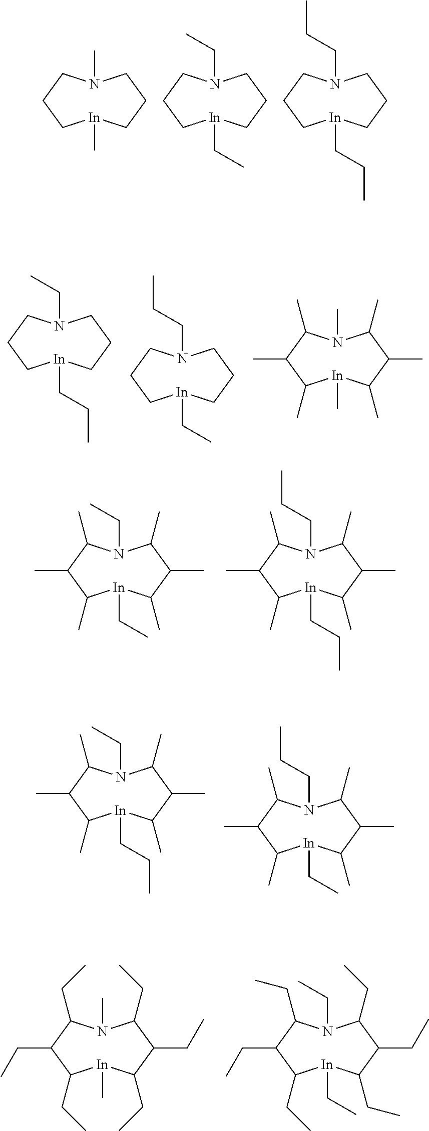

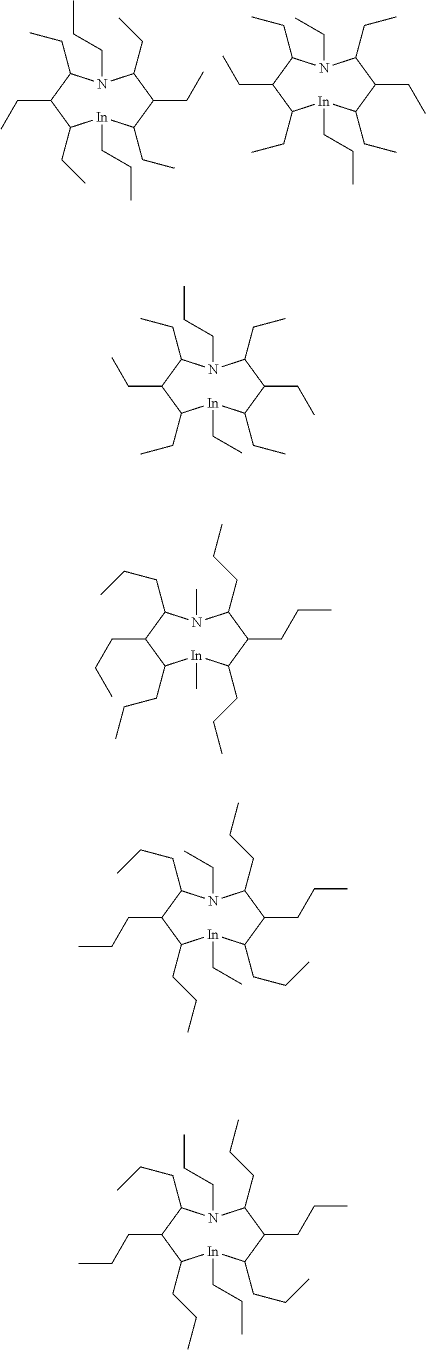

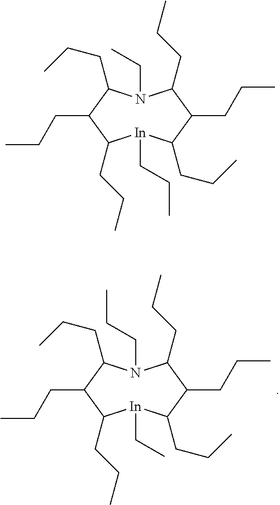

6. A composition for thin film deposition containing indium, comprising the indium compound of claim 1.

7. The composition for thin film deposition containing indium of claim 6, further comprising a gallium precursor and a zinc precursor.

8. A method for manufacturing an indium-containing thin film, comprising:
a) raising a temperature of a substrate mounted in a chamber;
b) injecting and adsorbing a composition for thin film deposition containing indium according to claim 6 to the substrate of which the temperature is raised; and
c) manufacturing an indium-containing thin film by injecting a reaction gas into the substrate to which the composition for thin film deposition containing indium is adsorbed.

9. The method for manufacturing an indium-containing thin film of claim 8, wherein the reaction gas is any one or two or more selected from the group consisting of oxygen (O₂), ozone (O₃), distilled water (H₂O), hydrogen peroxide (H₂O₂), nitrogen monoxide (NO), nitrous oxide (N₂O), nitrogen dioxide (NO₂), ammonia (NH₃), nitrogen (N₂), hydrazine (N₂H₄), amine, diamine, carbon monoxide (CO), carbon dioxide (CO₂), a saturated or unsaturated C₁ to C₁₂ hydrocarbon, hydrogen (H₂), argon (Ar), and helium (He).

10. The method for manufacturing an indium-containing thin film of claim 8, wherein a temperature of the substrate in step a) is 200 to 600° C.

11. A method for manufacturing an indium-containing thin film, comprising:
a) raising a temperature of a substrate mounted in a chamber;
b) injecting and adsorbing a composition for thin film deposition containing indium according to claim 7 to the substrate of which the temperature is raised; and
c) manufacturing an indium-containing thin film by injecting a reaction gas into the substrate to which the composition for thin film deposition containing indium is adsorbed.

12. The method for manufacturing an indium-containing thin film of claim 11, wherein the reaction gas is any one or two or more selected from the group consisting of oxygen (O2), ozone (O3), distilled water (H2O), hydrogen peroxide (H2O2), nitrogen monoxide (NO), nitrous oxide (N2O), nitrogen dioxide (NO2), ammonia (NH3), nitrogen (N2), hydrazine (N2H4), amine, diamine, carbon monoxide (CO), carbon dioxide (CO2), a saturated or unsaturated C1 to C12 hydrocarbon, hydrogen (H2), argon (Ar), and helium (He).

13. The method for manufacturing an indium-containing thin film of claim 11, wherein a temperature of the substrate in step a) is 200 to 600° C.
